(19) United States
(12) Patent Application Publication
(10) Pub. No.: US 2026/0362733 A1
(43) Pub. Date: Nov. 12, 2026

(54) SEMICONDUCTOR FIELD-EFFECT TRANSISTOR AND POWER AMPLIFIER INCLUDING THE SAME

(71) Applicant: ULTRABAND TECHNOLOGIES, INC., Zhubei City (TW)

(72) Inventor: Chan-Shin WU, Zhubei City (TW)

(73) Assignee: ULTRABAND TECHNOLOGIES, INC., Zhubei City (TW)

(21) Appl. No.: 19/671,428

(22) Filed: May 8, 2026

Related U.S. Application Data
(60) Provisional application No. 63/802,640, filed on May 9, 2025.

(30) Foreign Application Priority Data
Mar. 30, 2026 (TW) 115112487

(51) Int. Cl. H10D 30/47; H03F 3/217; H10D 62/10; H10D 62/60; H10D 62/824; H10D 64/23; H10D 64/27; H10D 64/60; H10D 64/62; H10D 64/64

(52) U.S. Cl. CPC H10D 30/475; H03F 3/2171; H10D 30/4755; H10D 62/102; H10D 62/60; H10D 62/824; H10D 64/256; H10D 64/411; H10D 64/602; H10D 64/62; H10D 64/64

(57) ABSTRACT

The present disclosure provides a semiconductor field-effect transistor including a channel layer; a barrier layer disposed above the channel layer; a gate disposed above the barrier layer; and a source and a drain respectively disposed on two sides of the gate; where the barrier layer includes a p-type layer. The advantage of the semiconductor field-effect transistor and the power amplifier including the same is that, by introducing a p-type layer in the barrier layer of the semiconductor field-effect transistor, the Schottky barrier height of the semiconductor field-effect transistor can be increased, reducing the gate leakage current, and so that its transconductance (gm) can more easily be maintained at a constant or stable value under forward bias, enlarging the depletion region, which can further make the threshold voltage shift positively.

### CROSS REFERENCE TO RELATED APPLICATION

This non-provisional application claims priority under 35 U.S.C. § 119(e) on US provisional Patent Application No(s).63/802,640 filed on May 09, 2025, and under 35 U.S.C. § 119(a) on Patent Application No(s). 115112487 filed in Taiwan, R.O.C. on Mar. 30, 2026, the entire contents of which are hereby incorporated by reference.

### BACKGROUND OF THE INVENTION

### Field of the Invention

The present disclosure mainly relates to a semiconductor apparatus, and in particular, to a semiconductor field-effect transistor and a power amplifier including the same, but the present disclosure is not limited thereto.

### Description of the Related Art

A semiconductor field-effect transistor is an electronic element that controls a current through the field effect, and a structure of the semiconductor field-effect transistor includes a gate, a source, and a drain. Specifically, a current flow between the drain and the source is controlled by using a voltage between the gate and the source.

Types of the semiconductor field-effect transistor include: a high electron mobility transistor, an insulated-gate bipolar transistor, a junction field-effect transistor, a metal-semiconductor field-effect transistor, a metal-oxide-semiconductor field-effect transistor, and the like. In the metal-semiconductor field-effect transistor, a gate is formed by using a Schottky barrier, and the metal-semiconductor field-effect transistor usually includes a compound semiconductor such as gallium nitride, gallium arsenide, indium phosphide, or silicon carbide. In addition, the metal-semiconductor field-effect transistor is widely used in communication in a microwave frequency band and a device such as a radar.

### BRIEF SUMMARY OF THE INVENTION

When being used in enhancement-mode field-effect transistors (E-mode FETs), conventional semiconductor field-effect transistors easily have a current leakage problem during forward bias due to a low Schottky barrier height. When the conventional semiconductor field-effect transistors are applied to depletion-mode field-effect transistors (D-mode FETs), a similar problem also occurs, to be specific, a situation in which the low barrier height may lead to breakdown or sub-threshold leakage. To resolve the foregoing technical problem, the present inventor discovers that, when a p-type layer is introduced in a barrier layer of a semiconductor field-effect transistor, an effective Schottky barrier height of the semiconductor field-effect transistor can be increased, and a gate leakage current of the semiconductor field-effect transistor can be reduced, and transconductance (gₘ) of the semiconductor field-effect transistor can be more easily maintained at a constant or stable value under the forward bias, and a depletion region of the semiconductor field-effect transistor can also be enlarged, so that a threshold voltage of the semiconductor field-effect transistor can be shifted positively.

Specifically, an aspect of the present disclosure provides a semiconductor field-effect transistor, including: a channel layer; a barrier layer disposed above the channel layer; a gate disposed above the barrier layer; and a source and a drain that are respectively disposed on two sides of the gate. The barrier layer includes a p-type layer.

According to some embodiments of the present disclosure, the channel layer includes InGaAs.

According to some embodiments of the present disclosure, the channel layer includes silicon-doped InGaAs.

According to some embodiments of the present disclosure, a thickness of the channel layer ranges from 80 angstroms to 250 angstroms.

According to some embodiments of the present disclosure, the barrier layer includes AlGaAs, GaAs, or GaN.

According to some embodiments of the present disclosure, the p-type layer includes p-doped AlGaAs, p-doped GaAs, or p-doped GaN.

According to some embodiments of the present disclosure, the p-type layer includes the p-doped AlGaAs, and an Al content of the p-type layer ranges from 15% to 30%.

According to some embodiments of the present disclosure, a doping concentration of the p-type layer ranges from 0.5 * 10¹² cm^{–2} to 2.5 * 10¹² cm^{–2}.

According to some embodiments of the present disclosure, a thickness of the p-type layer ranges from 20 angstroms to 60 angstroms.

According to some embodiments of the present disclosure, a capping layer is further disposed above the barrier layer and surrounding the gate. The capping layer includes GaAs.

According to some embodiments of the present disclosure, the capping layer is an n-doped layer, and a thickness of the capping layer ranges from 250 angstroms to 400 angstroms.

According to some embodiments of the present disclosure, the gate includes a gate electrode, and the gate electrode is in contact with the p-type layer.

According to some embodiments of the present disclosure, the gate includes the gate electrode, and the gate electrode includes titanium (Ti), platinum (Pt), gold (Au), or a combination thereof.

According to some embodiments of the present disclosure, the gate electrode is a titanium/platinum/gold alloy or a platinum/titanium/platinum/gold alloy.

According to some embodiments of the present disclosure, the source and the drain respectively include a source electrode and a drain electrode. The source electrode and the drain electrode each include a gold germanium (AuGe) alloy, nickel (Ni), gold (Au), or a combination thereof.

According to some embodiments of the present disclosure, the source electrode and the drain electrode are each a gold germanium/nickel/gold alloy.

According to some embodiments of the present disclosure, the source electrode and the drain electrode are each in contact with the channel layer.

According to some embodiments of the present disclosure, the semiconductor field-effect transistor is a modulation-doped field-effect transistor (MODFET), a high electron mobility transistor (HEMT), a metal-oxide-semiconductor field-effect transistor (MOSFET), a metal-semiconductor field-effect transistor (MESFET), or a metal-insulator-semiconductor field-effect transistor (MISFET).

Another aspect of the present disclosure provides a power amplifier, including the foregoing semiconductor field-effect transistor.

Advantages of the semiconductor field-effect transistor and the power amplifier including the same provided in the present disclosure are as follows: at a position corresponding to below the gate, the p-type layer is introduced in the barrier layer of the semiconductor field-effect transistor, so that the Schottky barrier height of the semiconductor field-effect transistor can be increased, the gate leakage current of the semiconductor field-effect transistor can be reduced, the transconductance (gₘ) of the semiconductor field-effect transistor can be more easily maintained at a constant or stable value under the forward bias, and the depletion region of the semiconductor field-effect transistor can be enlarged, so that the threshold voltage of the semiconductor field-effect transistor can be shifted positively.

### BRIEF DESCRIPTION OF THE DRAWINGS

To make the foregoing and other objectives, features, advantages, and embodiments of this application clearer, the accompanying drawings are described as follows.

FIG. 1 is a cross-sectional diagram of a structure of a semiconductor field-effect transistor according to an embodiment of the present disclosure.

FIG. 2 is a cross-sectional diagram of a structure of a semiconductor field-effect transistor according to an embodiment of the present disclosure.

According to conventional practice, various features and elements in the drawings are not drawn based on an actual proportion, and a drawing manner of the drawings is intended to present specific features and elements related to the present disclosure in an optimal manner. In addition, in different drawings, same or similar reference numerals are used to represent similar elements and components.

### DETAILED DESCRIPTION OF THE INVENTION

To make descriptions of the present disclosure more detailed and complete, illustrative descriptions of aspects and specific embodiments of the present disclosure are provided below, but the descriptions are not the only form in which the specific embodiments of the present disclosure are implemented or used. In this specification and the appended claims, unless otherwise specified in the context, "a" and "the" may also be explained as a plurality. In addition, in this specification and the appended claims, unless otherwise specified, "disposed on an object" may be considered as directly or indirectly attached or in contact with a surface of the object. Definition of the surface should be determined based on paragraph meanings before and after the content of this specification and general knowledge of the field to which the present disclosure belongs.

Although numerical ranges and parameters used to define the present disclosure are approximate values, related values in the specific embodiments are presented as precisely as possible herein. However, any value essentially inevitably contains a standard deviation caused by an individual test method. "About" usually indicates that an actual value is within plus or minus 10%, 5%, 1%, or 0.5% of a particular value or range. Alternatively, the term "about" represents that the actual value falls within an acceptable standard error of an average value, and is determined by consideration of a person of ordinary skill in the art to which the present disclosure belongs. Therefore, unless otherwise specified to the contrary, numerical parameters disclosed in this specification and the accompanying patent scope are the approximate values, and may be modified as required. These numerical parameters should be at least understood as a significant digit and a numerical value obtained by using a common rounding method.

In addition, blocks shown in the drawings in this specification may be used to represent functions, steps, or hardware, and do not necessarily correspond to physically or logically independent entities. Further, each block shown in the drawings may be implemented in a form of software, hardware, or a combination thereof.

The "semiconductor material" described in this specification may include chemical compounds of a plurality of elements. The chemical compound may include pairs formed by elements of Group 13 (where the group contains boron (B), aluminum (Al), gallium (Ga), indium (In), and thallium (Tl)) and Group 15 (where the group contains nitrogen (N), phosphorus (P), arsenic (As), antimony (Sb), and bismuth (Bi)), or pairs formed by elements of Group 14 (where the group contains elements such as carbon (C), silicon (Si), germanium (Ge), and tin (Sn)), such as silicon carbide (SiC) or silicon germanium alloys. Group 13 to Group 15 of the periodic table may be respectively referred to as Group III, Group IV, and Group V.

The present disclosure relates to a semiconductor field-effect transistor. The semiconductor field-effect transistor is preferably a compound semiconductor field-effect transistor. However, according to different embodiments, the semiconductor field-effect transistor may alternatively be a modulation-doped field-effect transistor (MODFET), a metal-oxide-semiconductor field-effect transistor (MOSFET), a metal-semiconductor field-effect transistor (MESFET), or a metal-insulator-semiconductor field-effect transistor (MISFET). Preferably, the semiconductor field-effect transistor is an enhancement-mode field-effect transistor. Specifically, the metal-oxide-semiconductor field-effect transistor in this specification may be an n-type or p-type silicon-based metal-oxide-semiconductor field-effect transistor (Si-MOSFET), or an n-type or p-type silicon-carbide-based metal-oxide-semiconductor field-effect transistor (SiC-MOSFET). The semiconductor field-effect transistor may be a plane transistor or a non-plane transistor, such as a fin field-effect transistor (FinFET) or a gate-all-around field-effect transistor (GAAFET).

In addition, the semiconductor field-effect transistor provided in the present disclosure may be disposed in a power amplifier.

### Embodiment s

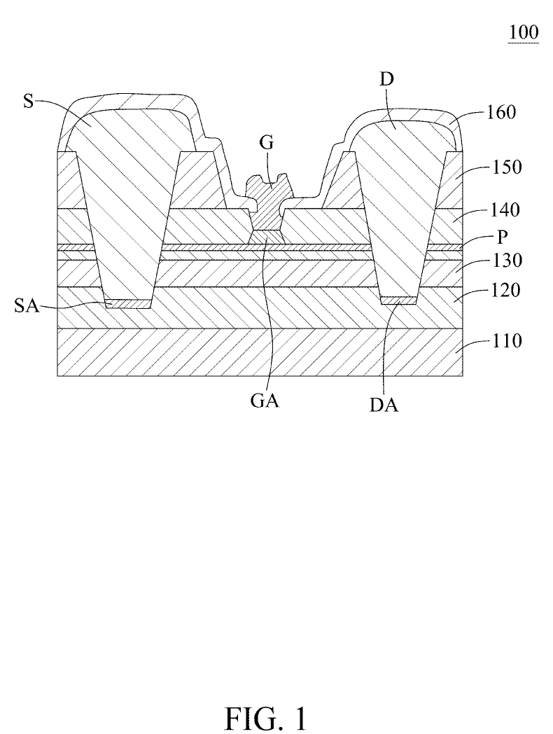

FIG. 1 is a cross-sectional diagram of a structure presented by a semiconductor field-effect transistor 100 according to an embodiment of the present disclosure. The semiconductor field-effect transistor 100 is an epitaxially grown layer structure, which includes the following main layer structures: a channel layer 130; a barrier layer 140 disposed above the channel layer 130; a gate G disposed above the barrier layer 140; and a source S and a drain D that are respectively disposed at two ends of the gate G. The barrier layer 140 includes a p-type layer P.

According to at least one embodiment of the present disclosure, the semiconductor field-effect transistor 100 further includes: a substrate 110, disposed below the channel layer 130; a buffer layer 120 disposed between the substrate 110 and the channel layer 130; a capping layer 150 disposed above the barrier layer 140 and surrounding the gate G; and a top capping layer 160 disposed to cover at least a part of the source S, the drain D, and the capping layer 150.

According to at least one embodiment of the present disclosure, the substrate 110 includes a wafer and needs to be insulated or semi-insulated, for example, a wafer produced by using a high-quality single-crystal silicon semiconductor material, such as sapphire, GaN, GaAs, silicon crystal, any polymorph of silicon carbide (SiC) (including wurtzite), AlN, InP, or a similar substrate material for a semiconductor. Preferably, the substrate 110 is a semi-insulated GaAs substrate, which can avoid substrate current interference, and is single crystal and suitable for forming a high-quality III-V epitaxial structure.

According to at least one embodiment of the present disclosure, the buffer layer 120 has an appropriate lattice structure and/or thermal expansion coefficient, to compensate for mismatching between the substrate 110 and other layer structures. The buffer layer 120 may include a compound semiconductor material, such as undoped, unintentionally doping (UID) or carbon doping (C doping) GaN or AlN. The material of the buffer layer 120 may be formed through epitaxial growth. Alternatively, the material of the buffer layer 120 may be formed into a thin film structure by using other thin film formation techniques such as chemical vapor deposition.

According to a preferred embodiment of the present disclosure, the channel layer 130 includes InGaAs. Preferably, the channel layer 130 includes silicon-doped InGaAs, to provide higher electron mobility and obtain a quicker response and a more excellent frequency operation capability. According to another embodiment of the present disclosure, a thickness of the channel layer 130 ranges from 80 angstroms to 250 angstroms, and may be specifically, for example, one of the following values or any value between any two of the following values: 80 angstroms, 90 angstroms, 100 angstroms, 110 angstroms, 120 angstroms, 130 angstroms, 140 angstroms, 150 angstroms, 160 angstroms, 170 angstroms, 180 angstroms, 190 angstroms, 200 angstroms, 210 angstroms, 220 angstroms, 230 angstroms, 240 angstroms, and 250 angstroms. Preferably, when the thickness of the channel layer 130 ranges from 80 angstroms to 120 angstroms, both good stress and good electrical property performance can be achieved. Without being limited to a particular theory, if the thickness is excessively thick, stress performance may be unideal. However, if the thickness is excessively thin, an electrical property of a device may also be negatively affected.

According to at least one embodiment of the present disclosure, the barrier layer 140 includes AlGaAs, GaAs, or GaN. Preferably, without being limited to a particular theory, a material of the barrier layer 140 is the AlGaAs because the AlGaAs has a wide bandgap. According to at least one embodiment of the present disclosure, a thickness of the barrier layer 140 ranges from 1.5 nm to 25.0 nm, and may be specifically, for example, one of the following values or any value between any two of the following values: 1.5 nm, 5.0 nm, 10.0 nm, 15.0 nm, 20.0 nm, and 25.0 nm. Preferably, the thickness ranges from 10.0 nm to 18.0 nm, to achieve an optimal threshold voltage. Meanwhile, without being limited to a particular theory, the gate G has a gate length, and generally, a ratio of the gate length to a distance between the gate G and the channel layer 130 needs to be greater than 5. Therefore, a larger thickness of the barrier layer 140 indicates a longer distance between the gate G and the channel layer 130, leading to a longer gate length. As a result, it is difficult to use the semiconductor field-effect transistor 100 in a radio frequency component product having a short gate length.

According to at least one embodiment of the present disclosure, the p-type layer P is disposed in the barrier layer 140 and below the gate. The p-type layer P includes p-doped AlGaAs, p-doped GaAs, or p-doped GaN. When a material of the p-type layer P is the p-doped AlGaAs, an Al content of the p-type layer P ranges from 15% to 30%, preferably ranges from 20% to 28%, and is more preferably 24%. Without being limited to a particular theory, if the Al content of the p-type layer P is excessively low, performance of charge transfer is poorer. If the Al content of the p-type layer P is excessively high, it is more difficult to perform high-concentration doping on the p-type layer P. In addition, the p-type layer P is preferably doped with carbon or beryllium, and is preferably formed by using a delta-doping technique. According to at least one embodiment of the present disclosure, a doping concentration of the p-type layer P ranges from 2 * 10¹⁸ cm^{–3} to 2 * 10¹⁹ cm^{–3}, and may be specifically, for example, one of the following values or any value between any two of the following values: 2.0 * 10¹⁸ cm^{–3}, 4.0 * 10¹⁸ cm^{–3}, 6.0 * 10¹⁸ cm^{–3}, 8.0 * 10¹⁸ cm^{–3}, 1.0 * 10¹⁹ cm^{–3}, 1.2 * 10¹⁹ cm^{–3}, 1.4 * 10¹⁹ cm^{–3}, 1.6 * 10¹⁹ cm^{–3}, 1.8 * 10¹⁹ cm^{–3}, and 2.0 * 10¹⁹ cm^{–3}. According to at least one embodiment of the present disclosure, a thickness of the p-type layer P ranges from 20 angstroms to 80 angstroms, and may be specifically, for example, one of the following values or any value between any two of the following values: 20 angstroms, 25 angstroms, 30 angstroms, 35 angstroms, 40 angstroms, 45 angstroms, 50 angstroms, 55 angstroms, and 60 angstroms. Preferably the thickness ranges from 20 angstroms to 40 angstroms.

Without being limited to a particular theory, if the doping concentration of the p-type layer P is excessively low at a specified thickness, a threshold voltage of the semiconductor field-effect transistor 100 is shifted negatively. If the doping concentration of the p-type layer P is excessively high at the specified thickness, the threshold voltage is shifted positively. However, as stated above, the ratio of the gate length of the gate G to the distance between the gate G and the channel layer 130 needs to be greater than 5. Therefore, a larger thickness of the p-type layer P indicates a longer distance between the gate G and the channel layer 130, leading to a longer gate length. As a result, it is difficult to use the semiconductor field-effect transistor 100 in a radio frequency component product having a short gate length.

According to a preferred embodiment of the present disclosure, the material of the barrier layer 140 is the same as that of the p-type layer P, to resolve a problem of bandgap reduction caused by mismatching of electrical properties (such as bandgap discontinuity) between different materials. Specifically, for example, the material of the barrier layer 140 is the AlGaAs and the material of the p-type layer P is the p-doped AlGaAs. Alternatively, the material of the barrier layer 140 is the GaAs and the material of the p-type layer P is p-doped GaAs. Alternatively, the material of the barrier layer 140 is GaN and the material of the p-type layer P is p-doped GaN.

According to at least one embodiment of the present disclosure, the capping layer 150 includes GaAs. Preferably, the capping layer 150 is an n-doped layer (for example, the capping layer is an n-doped GaAs layer), which can be used to avoid surface depletion, stabilize an electron concentration, and maintain channel conduction, thereby reducing a series resistance, improving electric field management, and increasing a breakdown voltage. In terms of structure, a thickness of the capping layer 150 ranges from 250 angstroms to 400 angstroms, and may be specifically, for example, one of the following values or any value between any two of the following values: 250 angstroms, 260 angstroms, 270 angstroms, 280 angstroms, 290 angstroms, 300 angstroms, 310 angstroms, 320 angstroms, 330 angstroms, 340 angstroms, 350 angstroms, 360 angstroms, 370 angstroms, 380 angstroms, 390 angstroms, and 400 angstroms. Preferably, the thickness ranges from 300 angstroms to 350 angstroms.

According to a preferred embodiment of the present disclosure, the semiconductor field-effect transistor 100 is respectively provided with an etch stop layer (not shown in the figure) at a bottom of the capping layer 150 and above the p-type layer P in the barrier layer 140, so that operability of the semiconductor field-effect transistor 100 in an epitaxial process can be improved. Preferably, the etch stop layer includes InGaP, and a thickness of the etch stop layer ranges from 20 angstroms to 50 angstroms, and may be specifically, for example, one of the following values or any value between any two of the following values: 20 angstroms, 25 angstroms, 30 angstroms, 35 angstroms, 40 angstroms, 45 angstroms, and 50 angstroms. In addition, without being limited to a particular theory, through disposition of the two etch stop layers, the gate G is disposed in a double recess structure, thereby achieving effects such as reducing gate leakage, improving electric field distribution uniformity (avoiding a field strength peak), and improving control of the gate G on the channel layer 130.

According to at least one embodiment of the present disclosure, the gate G includes a gate electrode. A material of the gate electrode is titanium (Ti), platinum (Pt), gold (Au), or a combination thereof. Preferably, the gate electrode is a titanium/platinum/gold alloy or a platinum/titanium/platinum/gold alloy. Specifically, the gate electrode includes a gate electrode alloyed region GA, which is a region formed after the gate electrode is alloyed, and is in contact with the p-type layer P, to form ohmic contact. According to a preferred embodiment of the present disclosure, a platinum layer may be further formed at a bottom (that is, a region in contact with the p-type layer P) of the gate electrode alloyed region GA through platinum sinking. A thickness of the platinum layer ranges from 50 angstroms to 90 angstroms, and may be specifically, for example, one of the following values or any value between any two of the following values: 50 angstroms, 55 angstroms, 60 angstroms, 65 angstroms, 70 angstroms, 75 angstroms, 80 angstroms, 85 angstroms, and 90 angstroms. Therefore, an effective Schottky barrier height can be improved.

According to at least one embodiment of the present disclosure, the source S and the drain D respectively include a source electrode and a drain electrode. The source electrode and the drain electrode each include a gold germanium (AuGe) alloy, nickel (Ni), gold (Au), or a combination thereof. Preferably, both the source electrode and the drain electrode are a gold germanium/nickel/gold alloy. Specifically, the source electrode and the drain electrode respectively include a source electrode alloyed region SA and a drain electrode alloyed region DA, which are respectively regions formed after the source electrode and the drain electrode are alloyed, and are both in ohmic contact with the channel layer 130. According to a preferred embodiment of the present disclosure, the source electrode and the drain electrode are both in contact with the channel layer 130. More preferably, the source electrode and the drain electrode are both in contact with the channel layer 130, the barrier layer 140, and the capping layer 150. In other words, etching depths of the source S and the drain D need to be greater than or equal to a distance between an upper surface of the capping layer 150 and an upper surface of the channel layer 130 in a process. Therefore, without being limited to a particular theory, an effect of the ohmic contact is more ideal, so that the semiconductor field-effect transistor 100 has a better electrical property.

Through testing, in comparison with a conventional semiconductor field-effect transistor, a Schottky barrier height of the semiconductor field-effect transistor 100 disposed based on the foregoing content can be increased by approximately 0.10 eV to 0.25 eV, and a depletion region of the semiconductor field-effect transistor 100 is large, so that the threshold voltage of the semiconductor field-effect transistor 100 is further positively increased by approximately 0.1 V to 0.3 V.

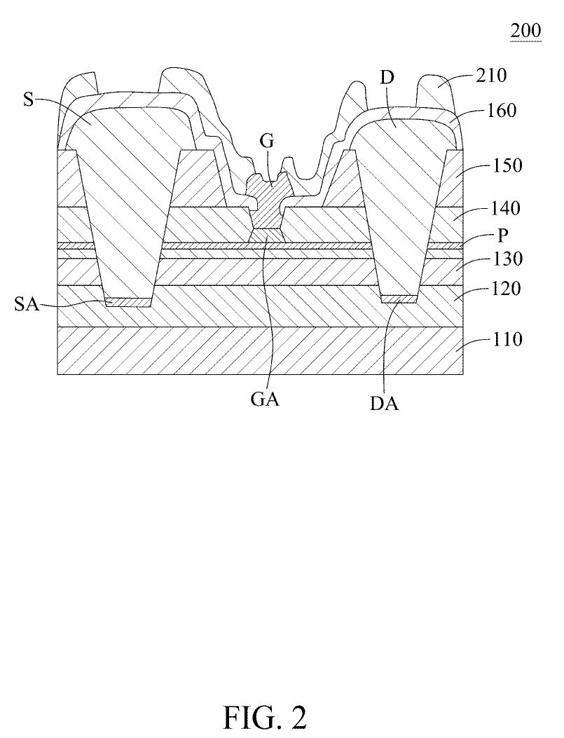

In addition, the present disclosure further provides a semiconductor field-effect transistor 200 according to another embodiment of the present disclosure. FIG. 2 is a cross-sectional diagram of a structure of a semiconductor field-effect transistor 200 according to at least one embodiment of the present disclosure. With reference to FIGS. 1 and 2 together, structures presented by the two figures are basically similar. A difference lies in that the semiconductor field-effect transistor 200 further includes a passivation layer 210, which covers at least a part of upper surfaces of the source S, the gate G, and the drain D. Preferably, the passivation layer 210 may be a gate oxide layer or a silicon nitride (Si₃N₄) material, so that surface defects of the semiconductor field-effect transistor 200 can be passivated, a surface leakage current can be suppressed, and a breakdown voltage can be improved.

In conclusion, advantages of the semiconductor field-effect transistor and the power amplifier including the same provided in the present disclosure are as follows: the p-type layer is disposed in the barrier layer of the semiconductor field-effect transistor, so that the Schottky barrier height of the semiconductor field-effect transistor can be increased, and the gate leakage current of the semiconductor field-effect transistor can be reduced. Therefore, the transconductance (gₘ) of the semiconductor field-effect transistor can be more easily maintained at a constant or stable value under forward bias, and the depletion region of the semiconductor field-effect transistor can also be enlarged, so that the threshold voltage of the semiconductor field-effect transistor can be shifted positively.

In this specification, all ranges provided are intended to include each particular range within the given ranges and combinations of subranges between the given ranges. In addition, unless otherwise specified, all ranges provided in this specification all include endpoints of the ranges. Therefore, a range of 1 to 5 specifically includes 1, 2, 3, 4, and 5, and sub-ranges such as 2 to 5, 3 to 5, 2 to 3, 2 to 4, and 1 to 4.

The present disclosure has been described above in detail. The foregoing descriptions are merely preferred embodiments of the present disclosure, but are not intended to limit the scope of implementing the present disclosure. In other words, any equivalent change or modification made according to the patent scope of the present disclosure shall fall within the patent scope of the present disclosure.

While the present disclosure has been described by means of specific embodiments, numerous modifications and variations could be made thereto by those skilled in the art without departing from the scope and spirit of the present disclosure set forth in the claims.

What is claimed is:

1. A semiconductor field-effect transistor, comprising:
a channel layer;
a barrier layer disposed above the channel layer;
a gate disposed above the barrier layer; and
a source and a drain that are respectively disposed on two sides of the gate, wherein
the barrier layer comprises a p-type layer.

2. The semiconductor field-effect transistor according to claim 1, wherein the channel layer comprises InGaAs.

3. The semiconductor field-effect transistor according to claim 2, wherein the channel layer comprises silicon-doped InGaAs.

4. The semiconductor field-effect transistor according to claim 2, wherein a thickness of the channel layer ranges from 80 angstroms to 250 angstroms.

5. The semiconductor field-effect transistor according to claim 1, wherein the barrier layer comprises AlGaAs, GaAs, or GaN.

6. The semiconductor field-effect transistor according to claim 1, wherein the p-type layer comprises p-doped AlGaAs, p-doped GaAs, or p-doped GaN.

7. The semiconductor field-effect transistor according to claim 6, wherein the p-type layer comprises the p-doped AlGaAs, and an Al content of the p-type layer ranges from 15% to 30%.

8. The semiconductor field-effect transistor according to claim 1, wherein a doping concentration of the p-type layer ranges from 0.5 * 10¹² cm^{–2}2to .5 * 10¹² cm^{–2}.

9. The semiconductor field-effect transistor according to claim 1, wherein a thickness of the p-type layer ranges from 20 angstroms to 60 angstroms.

10. The semiconductor field-effect transistor according to claim 1, wherein a capping layer is further disposed above the barrier layer and surrounding the gate, and the capping layer comprises GaAs.

11. The semiconductor field-effect transistor according to claim 10, wherein the capping layer is an n-doped layer, and a thickness of the capping layer ranges from 250 angstroms to 400 angstroms.

12. The semiconductor field-effect transistor according to claim 1, wherein the gate comprises a gate electrode, and the gate electrode is in contact with the p-type layer.

13. The semiconductor field-effect transistor according to claim 1, wherein the gate comprises a gate electrode, and the gate electrode comprises titanium (Ti), platinum (Pt), gold (Au), or a combination thereof.

14. The semiconductor field-effect transistor according to claim 13, wherein the gate electrode is a titanium/platinum/gold alloy or a platinum/titanium/platinum/gold alloy.

15. The semiconductor field-effect transistor according to claim 1, wherein the source and the drain respectively comprise a source electrode and a drain electrode, and the source electrode and the drain electrode each comprise a gold germanium (AuGe) alloy, nickel (Ni), gold (Au), or a combination thereof.

16. The semiconductor field-effect transistor according to claim 15, wherein the source electrode and the drain electrode are each a gold germanium/nickel/gold alloy.

17. The semiconductor field-effect transistor according to claim 15, wherein the source electrode and the drain electrode are each in contact with the channel layer.

18. The semiconductor field-effect transistor according to claim 1, wherein the semiconductor field-effect transistor is a modulation-doped field-effect transistor (MODFET), a high electron mobility transistor (HEMT), a metal-oxide-semiconductor field-effect transistor (MOSFET), a metal-semiconductor field-effect transistor (MESFET), or a metal-insulator-semiconductor field-effect transistor (MISFET).

19. A power amplifier, comprising the semiconductor field-effect transistor according to claim 1.
